(19) United States
(12) Patent Application Publication
(10) Pub. No.: US 2025/0164610 A1
(43) Pub. Date: May 22, 2025

(54) OPTICAL PACKAGE WITH COMPONENTS UNDER-STACKED

(71) Applicant: Namuga Co., Ltd., Gyeonggi-do (KR)

(72) Inventors: Jun Youb LEE, Gyeonggi-do (KR); Young Gyu KANG, Gyeonggi-do (KR); Dong Ho LEE, Gyeonggi-do (KR)

(73) Assignee: Namuga Co., Ltd., Gyeonggi-do (KR)

(21) Appl. No.: 18/952,048

(22) Filed: Nov. 19, 2024

(30) Foreign Application Priority Data
Nov. 20, 2023 (KR) 10-2023-0159999

(51) Int. Cl. G01S 7/481; G01S 17/894

(52) U.S. Cl. CPC G01S 7/4813; G01S 17/894

(57) ABSTRACT

An optical package has a light source module including a light source, a first component for driving the light source, and a light source board having a first side on which the light source is stacked and a second side on which the first component is under-stacked. The optical package has a main board in which a first region is open and to which the light source module is coupled so that the first component is positioned in the first region. Also, the optical package has a sensor module including an optical sensor board disposed to be spaced apart from the main board through a spacer, thereby defining a separation space, and a second component disposed in the separation space.

### CROSS REFERENCE TO RELATED APPLICATION

This application claims priority from Korean Patent Application No. 10-2023-0159999, filed on Nov. 20, 2023, which is hereby incorporated by reference for all purposes as if fully set forth herein.

### FIELD OF TECHNOLOGY

The present disclosure relates to an optical package.

### BACKGROUND

A time of flight (TOF) type 3D depth camera is a technology that measures the distance between an object and a camera based on the speed of light. This camera generally emits infrared light to a target. It measures the time it takes for this light to reach the target, reflect, and return to the camera. Based on this time information, the camera can calculate an exact distance to the target. The TOF camera has the advantage of being able to measure distances quickly and accurately in real time. Due to this characteristic, the TOF camera is utilized in various fields. For example, the TOF camera plays an important role in augmented reality (AR), virtual reality (VR), autonomous vehicles, robotics, and security systems.

The 3D depth camera may include a light source unit and a sensing unit.

The light source unit emits light to the target, and this light is reflected by the target and returns to the camera sensor to generate distance information. The light source unit may include a light source, an optical filter, a lens, a driver circuit, or the like.

A vertical-cavity surface-emitting laser (VCSEL) is mainly used as a light source. The VCSEL is a type of surface-emitting laser and has a vertical structure. The VCSEL consumes relatively low power compared to other types of lasers. This is very advantageous in a battery-operated device. In addition, the VCSEL has a very narrow beam divergence angle, and thus, it is possible to accurately focus light on a target. This increases the accuracy of distance measurement.

The light source unit includes a driver circuit for driving the VCSEL, and the driver circuit may include a driving integrated circuit (IC) and passive components such as a capacitor and a resistor. The driving IC may control the current of driving power supplied to the VCSEL. The driving IC may maintain the driving current at a constant value, and increase or decrease the level of the driving current as needed. The driving IC supports high-speed modulation, which enables accurate data transmission. Meanwhile, the VCSEL is generally driven in pulse mode, and for this purpose, the driving IC may be controlled to provide high current during a short pulse period.

The sensing unit may include an image sensor. The image sensor forms an image based on a signal from a photodetector. The photodetector included in the image sensor is a device that converts reflected light into an electrical signal. The photodetector mainly uses a high-sensitivity light-sensitive element such as a photodiode (PD) or an avalanche photodiode (APD). The photodetector detects reflected infrared light and converts the detected infrared light into an electrical signal to generate distance information.

The sensing unit may include a signal processing circuit. The signal processing circuit is a circuit that processes the signal of the reflected light. This circuit processes raw data and performs tasks such as filtering, amplification, and data conversion to finally provide distance information or 3D images in a form that can be understood by the user.

The sensing unit may include an optical filter and a lens. The sensing unit may include an optical filter and a lens that help to remove unwanted background light and effectively focus reflected light onto the sensor.

In this way, the camera includes various components in addition to the light source and the image sensor. For example, the driving IC, passive components, and signal processing circuits are included in the camera. These elements may cause problems such as an increase in the volume of the camera and difficulty in miniaturization. However, devices equipped with cameras such as smartphones and tablet PCs are gradually becoming smaller, and the component region excluding the display panel is narrowing, so the need for development of a technology for reducing the volume of the camera is increasing.

The discussions in this section are intended merely to provide background information and do not constitute an admission of prior art.

### SUMMARY

With respect to the above-described background, an object of the present embodiment is, in one aspect, to provide a technology capable of reducing a volume of an optical package including a light source module and a sensor module. In another aspect, an object of the present embodiment is to provide a technology for optimizing the arrangement of components to reduce signal loss and minimize the influence of noise. In another aspect, an object of the present embodiment is to provide a technology for efficiently discharging heat generated from a light source.

In order to achieve the above-described objects, according to one embodiment of the present disclosure, there is provided an optical package including: a light source module including a light source, a first component for driving the light source, and a light source board having a first side on which the light source is stacked and a second side on which the first component is under-stacked; a main board in which a first region is open and to which the light source module is coupled so that the first component is positioned in the first region; and a sensor module including an optical sensor board disposed to be spaced apart from the main board through a spacer, and a second component disposed in a separation space between the optical sensor board and the main board.

The spacer may include a first-stage spacer disposed on a lower side and a second-stage spacer disposed on an upper side of the first-stage spacer, the optical sensor board may be supported by the first-stage spacer, and an optical filter may be supported by the second-stage spacer.

The light source module may further include a light source module frame that surrounds the light source and supports an optical component upward, and a third component may be disposed in a separation space between the light source board and the optical component inside the light source module frame.

The light source module may be coupled to a first side of the main board, and a stiffener may be attached to a second side of the main board.

A portion of a part of the stiffener corresponding to the first region may be open.

A thermal interface material (TIM) may be injected into the open portion of the stiffener.

A portion where the light source is stacked on a first side surface of the light source board and a portion where the first component is under-stacked on a second side surface may not overlap each other in a direction perpendicular to the light source board.

The spacer may have an “L” shape in cross section, and the optical sensor board may be supported by a lower portion of the “L” shape, and the optical filter may be supported by a higher portion of the “L” shape.

A conductor electrically connecting an upper side and a lower side of the spacer may be disposed inside the spacer so as to penetrate the spacer, a connection pad may be formed on a lower side of the optical filter, one end of the connection pad may be in contact with a sensor pad formed on an upper side of the optical sensor board, and the other end of the connection pad may be in contact with the conductor.

The optical package may further include an optical holder that surrounds the sensor module and positions an optical receiving lens above the sensor module, and the optical holder may support the optical filter so that the optical filter is positioned between the optical receiving lens and the optical sensor board.

According to another embodiment of the present disclosure, there is provided an optical package including: a light source module including a light source, a first component for driving the light source, and a light source board having a first side on which the light source is stacked and a second side on which the first component is under-stacked; a main board which supplies electricity to the light source board while separating the light source board upwardly through a conductor spacer, and in which a fourth component is disposed in a separation space formed between the main board and the light source board by the conductor spacer; and a sensor module including an optical sensor board disposed to be spaced apart from the main board through a non-conductor spacer, and a second component disposed in a separation space between the optical sensor board and the main board.

The light source module may further include a light source module frame that surrounds the light source and supports an optical component upward, and a third component may be disposed in a separation space between the light source board and the optical component inside the light source module frame.

The light source module may be coupled to a first side of the main board, and a stiffener may be attached to a second side of the main board.

A portion where the light source is stacked on a first side surface of the light source board and a portion where the first component is under-stacked on a second side surface may not overlap each other in a direction perpendicular to the light source board.

The non-conductor spacer may include a first-stage spacer disposed on a lower side and a second-stage spacer disposed on an upper side of the first-stage spacer, and the optical sensor board is supported by the first-stage spacer, and an optical filter is supported by the second-stage spacer.

As described above, according to the present embodiment, the volume of the optical package including the light source module and the sensor module can be reduced, and the arrangement of components can be optimized to reduce signal loss and minimize the influence of noise. In addition, according to the present embodiment, heat generated from the light source can be efficiently discharged.

### BRIEF DESCRIPTION OF THE DRAWINGS

In order for the disclosure to be well understood, there are now described various forms thereof, given by way of example, reference being made to the accompanying drawings, in which:

FIG. 1 is a top view of an optical package according to a first embodiment.

FIG. 2 is a bottom view of an optical package according to the first embodiment.

FIG. 3 is a cross-sectional view taken along line A-A′ of FIG. 1 and a top view of a sensor module.

FIGS. 4A and 4B are first views illustrating a manufacturing process of the optical package according to the first embodiment.

FIGS. 5A and 5B are second views illustrating the manufacturing process of the optical package according to the first embodiment.

FIGS. 6A and 6B are third views illustrating the manufacturing process of the optical package according to the first embodiment.

FIGS. 7A and 7B are fourth views illustrating the manufacturing process of the optical package according to the first embodiment.

FIG. 8 is a view for explaining a light source module according to the first embodiment.

FIG. 9 is an enlarged view of a two-dot chain line portion of FIG. 8.

FIG. 10 is a top view of the light source module according to the first embodiment.

FIG. 11 is a cross-sectional view taken along line C-C′ of FIG. 10.

FIG. 12 is a view before a driving IC is attached to a lower surface of the light source module according to the first embodiment.

FIG. 13 is a view after the driving IC is attached to the lower surface of a light source module according to the first embodiment.

FIG. 14 is a cross-sectional view of an optical package according to a second embodiment and a top view of a sensor module.

FIG. 15 is a view illustrating some components attached to a main board in an optical package according to a third embodiment.

FIG. 16 is a view illustrating that a light source module in FIG. 15 is completed.

FIG. 17 is a bottom view of the optical package according to the third embodiment.

FIG. 18 is a view for explaining the light source module according to the third embodiment.

FIG. 19 is an enlarged view of a two-dot chain line portion of FIG. 18.

FIG. 20 is a cross-sectional view of an optical package according to a fourth embodiment.

### DETAILED DESCRIPTION

Hereinafter, some embodiments of the present disclosure will be described in detail through exemplary drawings. When adding reference signs to components of each drawing, it should be noted that the same components are given the same signs as much as possible even if the same components are illustrated in different drawings. In addition, when describing the present disclosure, when it is judged that a specific description of a related known configuration or function may obscure the gist of the present disclosure, the detailed description thereof will be omitted.

In addition, when describing components of the present disclosure, terms such as first, second, A, B, (a), (b), or the like may be used. These terms are only intended to distinguish the components from other components, and the nature, order, or sequence of the components are not limited by the terms. When a component is described as being “connected”, “coupled”, or “joined” to another component, it should be understood that the component may be directly connected or joined to the other component, but another component may also be “connected,” “coupled,” or “joined” between components.

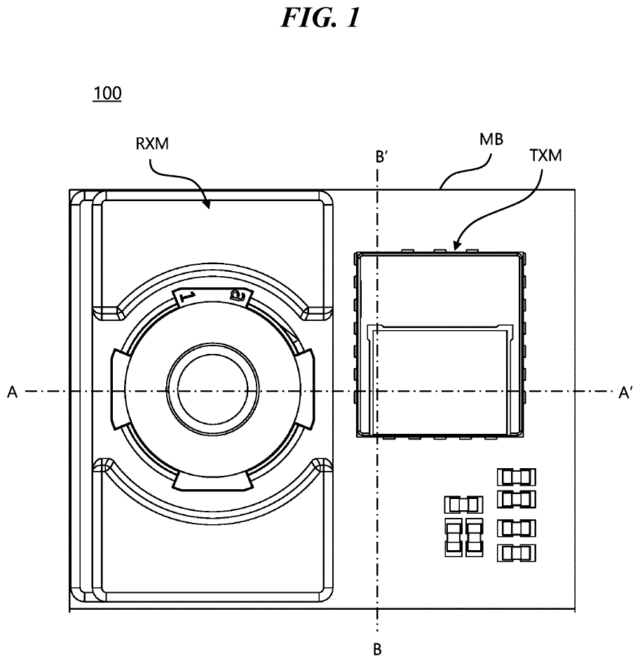

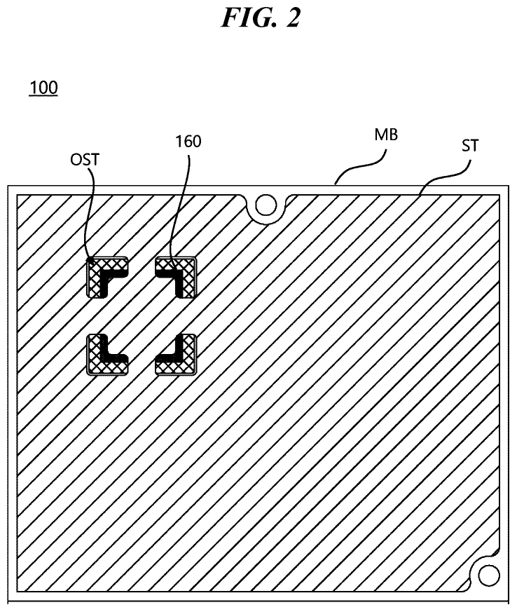

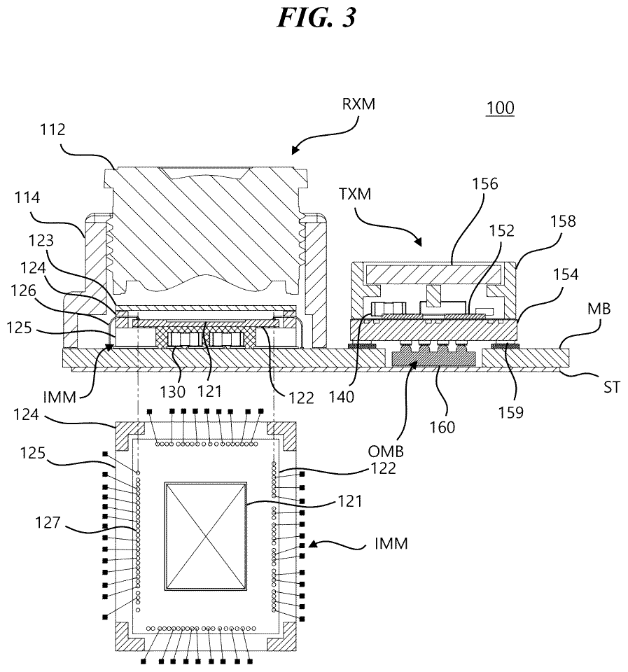

FIG. 1 is a top view of an optical package according to a first embodiment. Moreover, FIG. 2 is a bottom view of the optical package according to the first embodiment. Further, FIG. 3 is a cross-sectional view taken along line A-A′ of FIG. 1 and a top view of a sensor module.

Referring to FIGS. 1 to 3, an optical package 100 may include a main board MB, a receiving module RXM, and a light source module TXM.

The receiving module RXM and the light source module TXM may be coupled to one surface of the main board MB. Moreover, a stiffener ST may be coupled to the other surface of the main board MB. Hereinafter, for convenience of explanation, the surface of the main board MB to which the receiving module RXM is coupled is referred to as an upper surface, and the surface to which the stiffener ST is coupled is referred to as a lower surface. Moreover, a direction in which the receiving module RXM is coupled to the main board MB is referred to as an upper side and a direction opposite to the upper side is referred to as a lower side.

Referring to FIG. 2, some regions of the stiffener ST may be open. When this region is called a stiffener open region OST, the stiffener open region OST is formed in an “L” shape at the corner of a square, and a total of four may be formed. When viewed from the lower side of the main board MB, a driving IC 160 may be observed in the stiffener open region OST. As described below, a thermal interface material (TIM) may be injected into the stiffener open region OST, and the heat (more specifically, the heat of a light source 152) of the driving IC 160 and the heat of the light source module TXM may be quickly released to the outside by this TIM.

The thermal interface material (TIM) is a material used to effectively transfer and disperse heat generated in an electronic device. The TIM is applied between a heat source such as a light source 152 and a heat dissipation location (for example, outside air) to fill the air gap between the two surfaces and the fine surface irregularities to improve the heat conduction efficiency. The TIM plays an important role in minimizing the thermal resistance and increasing the reliability and lifespan of the device. There are various types of TIM and they vary depending on the material and form used. Typically, thermally conductive grease used as the TIM is a viscous and flexible material that is easy to apply and fills the irregularities between the two surfaces well. As another example, a thermally conductive pad is made of a flexible material such as rubber or silicone and is provided in the form of a pad with a certain thickness. In addition, a phase change material with high heat transfer efficiency may be used as a material that changes from a solid to a liquid state as the temperature rises, and a metal-based TIM in the form of a material including a metal powder such as silver or copper may also be used.

Referring to FIG. 3, the receiving module RXM may be disposed on the main board MB, and the light source module TXM may be disposed at a position close to the receiving module RXM on the main board MB.

The receiving module RXM may include a sensor module IMM. The sensor module IMM may be placed on the main board MB and may be surrounded by an optical holder 114.

The optical holder 114 may position an optical receiving lens 112 on the sensor module IMM. The optical receiving lens 112 may play a role in collecting light coming from the outside and accurately focusing the light on an optical sensor 121. The optical receiving lens 112 may adjust the angle of the incoming light to determine the range (angle of view) of the scene captured by the sensor module IMM. A wide-angle lens may capture a wide range, and a telephoto lens may capture a narrow range.

An optical filter 123 may be located on the sensor module IMM. The optical filter 123 may be used to selectively pass or block light of a specific wavelength. In addition, the optical filter 123 may minimize interference that may occur due to background light (for example, sunlight or artificial lighting) of the surrounding environment. This may improve the signal-to-noise ratio, thereby enabling accurate distance measurement.

The light source module TXM may include a light source board 154. In addition, the light source 152 may be stacked on the upper side of the light source board 154, and the driving IC 160 may be under-stacked on the lower side of the light source board 154. By stacking the light source 152 on one side of the light source board 154 and under-stacking the driving IC 160 on the opposite side, space occupancy of components may be minimized. In addition, as a distance between the light source 152 and the driving IC 160 is shortened, an electrical resistance between the driving IC 160 and the light source 152 is reduced, and thus, heat generation and signal loss caused by the electrical resistance can be minimized.

The light source 152 may be a vertical-cavity surface-emitting laser (VCSEL). The VCSEL is a type of surface-emitting laser and has a vertical structure. The VCSEL consumes relatively low power compared to other types of lasers. This is very advantageous for a battery-operated device. In addition, the VCSEL has a very narrow beam divergence angle, so that light can be accurately focused on a target. This increases the accuracy of distance measurement.

The light source module TXM may further include a light source module frame 158 that surrounds the light source 152 and supports an optical component 156 upwardly.

The light source module frame 158 may have a cross-section on one side shaped like a letter “┤”. In addition, a portion (a portion protruding horizontally with the light source board 154) protruding from the “┤” shape may support the optical component 156.

The optical component 156 may be, for example, a diffuser. The diffuser may evenly disperse the light emitted from the light source 152. This allows the light from the light source 152 to reach the target evenly. In addition, the diffuser may perform an eye protection function by reducing the intensity of light concentrated on one spot.

A certain separation space may be formed between the optical component 156 and the light source board 154. In addition, a component (for example, a capacitor, a resistor, or the like) may be arranged in this separation space.

The sensor module IMM may include an optical sensor board 122. The optical sensor 121 may be disposed on the optical sensor board 122, and wires connecting the optical sensor 121 and a signal processing circuit may be disposed.

The optical sensor board 122 may be positioned spaced apart from the main board MB toward the top. According to this arrangement, the optical noise of the light source module TXM coming through the main board MB may be minimized from being injected into the optical sensor 121.

The sensor module IMM may include spacers 125 and 124 to space the optical sensor board 122 away from the main board MB.

The spacers 125 and 124 may include a first-stage spacer 125 and a second-stage spacer 124. The first-stage spacer 125 may be attached to the main board MB and may support the optical sensor board 122 toward the upper side. The second-stage spacer 124 may be attached to the upper side of the first-stage spacer 125. Moreover, the second-stage spacer 124 may support the optical filter 123 upwardly.

The first-stage spacer 125 may be formed to have a constant thickness along the edge of the sensor module IMM having a rectangular shape. Moreover, the second-stage spacer 124 may be formed to have an ‘L’ shape at the corner of the rectangular shape.

The optical sensor board 122 is separated upwardly from the main board MB by the first-stage spacer 125, and a separation space can be formed between the optical sensor board 122 and the main board MB. Moreover, components 130 such as a signal processing circuit may be disposed in this separation space. These components 130 may prevent optical noise coming into the main board MB from being transmitted to the optical sensor board 122.

A sensor connection pad 127 may be formed at the edge of the optical sensor board 122, and this sensor connection pad 127 may be electrically connected to the main board MB through a wire 126. The light source module TXM may be electrically connected to the main board MB in such a way that the light source board connection pad 159 formed at the lower side of the light source board 154 is coupled to the main board MB.

An open region OMB may be formed in the main board MB. Then, the light source module TXM may be coupled to the main board MB so that the driving IC 160 is located in the open region OMB of the main board MB.

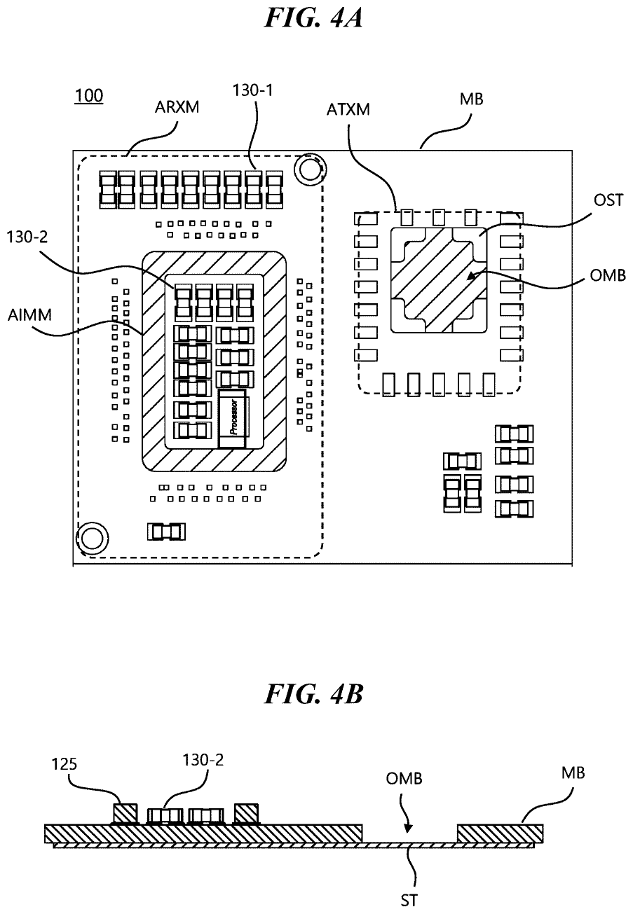

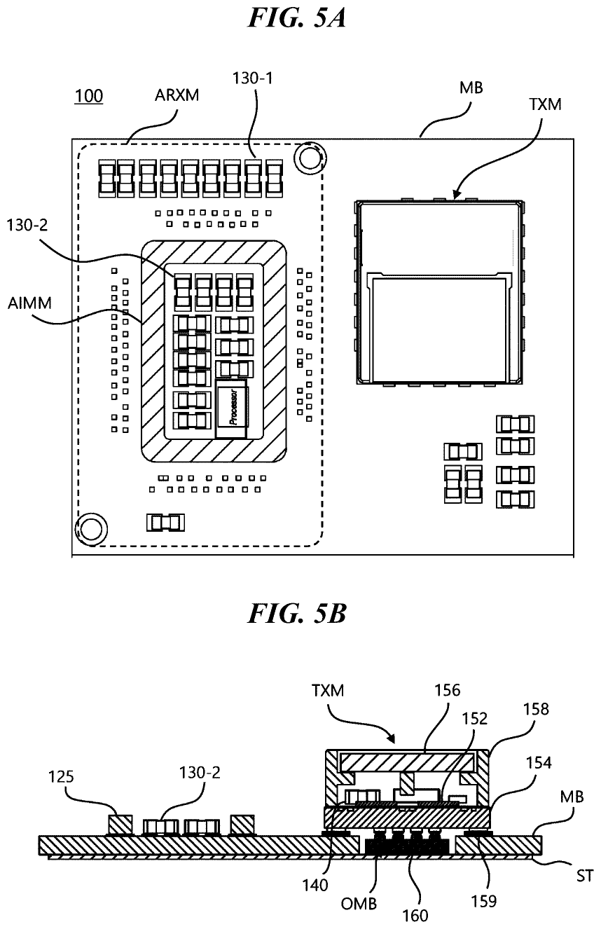

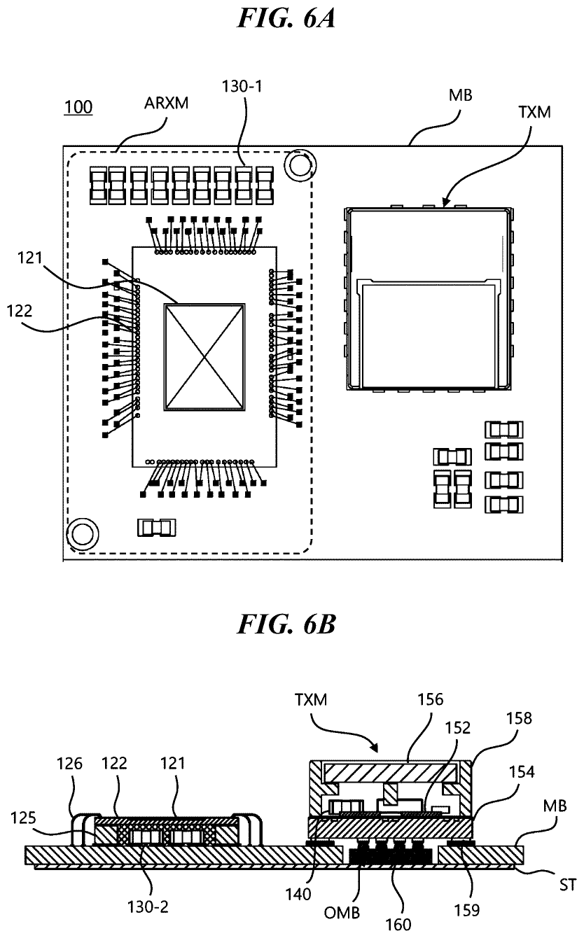

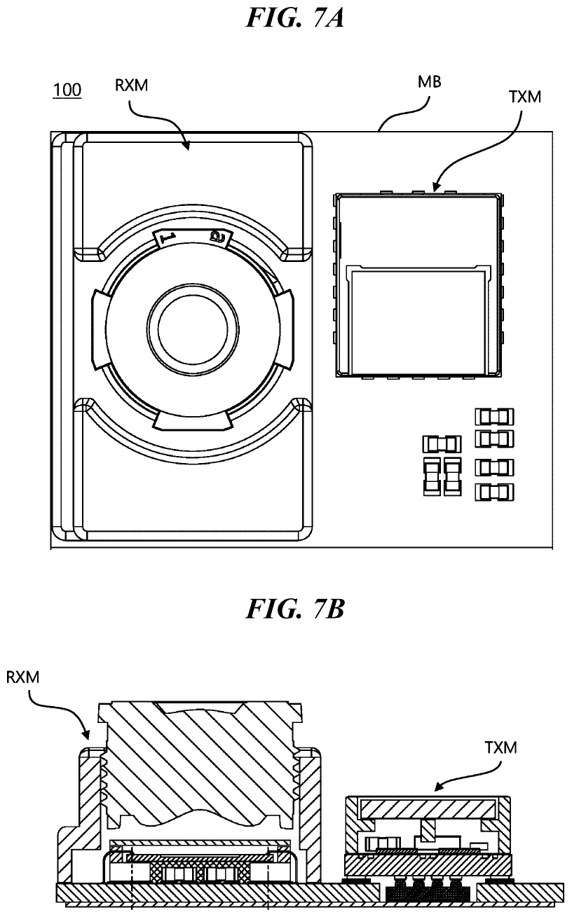

FIGS. 4A and 4B are first views illustrating a manufacturing process of the optical package according to the first embodiment, FIGS. 5A and 5B are second views illustrating the manufacturing process of the optical package according to the first embodiment, FIGS. 6A and 6B are third views illustrating the manufacturing process of the optical package according to the first embodiment, and FIGS. 7A and 7B are fourth views illustrating the manufacturing process of the optical package according to the first embodiment.

Referring to FIGS. 4A and 4B, the open region OMB may be formed on the main board MB. Then, the stiffener ST may be attached to the lower side of the main board MB.

Components may be disposed on the upper side of the main board MB. Some of these components may be located outside the light source module region ATXM and the receiving module region ARXM, and other portions 130-1 may be located inside the receiving module region ARXM. Moreover, some other portions 130-2 may be located inside the sensor module region AIMM. The components 130-2 disposed inside the sensor module region AIMM may include a signal processing processor that processes a signal output from an optical sensor, and may include signal processing circuit components that support the operation of the signal processing processor.

The sensor module region AIMM is partitioned while the first-stage spacer 125 is formed on the main board MB, the components 130-2 that process the signal of the optical sensor may be located inside the sensor module region AIMM.

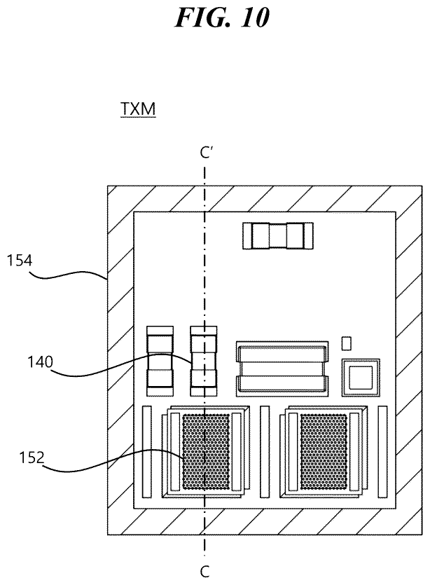

Referring to FIGS. 5A and 5B, the light source module TXM may be coupled to the main board MB so that the driving IC 160 is located in the open region OMB of the main board MB. The light source module TXM may be manufactured in advance through a separate process, and the manufacturing process of the light source module TXM will be described later with reference to FIGS. 10 to 13.

Referring to FIGS. 6A and 6B, the optical sensor board 122 is attached on the first-stage spacer 125 attached in advance, and the optical sensor board 122 and the main board MB may be electrically connected to each other through the wire 126.

Referring to FIGS. 7A and 7B, the second-stage spacer can be positioned on the first-stage spacer, and the optical filter can be placed on the second-stage spacer. Then, a holder may be disposed to surround the sensor module, thereby completing the receiving module RXM.

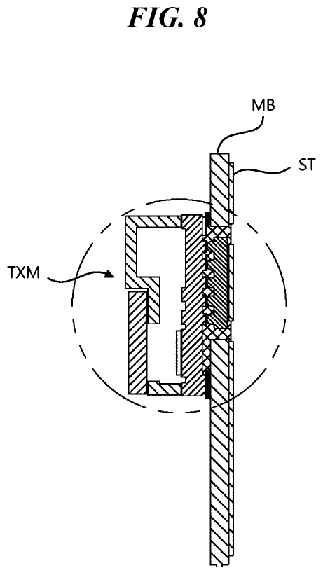

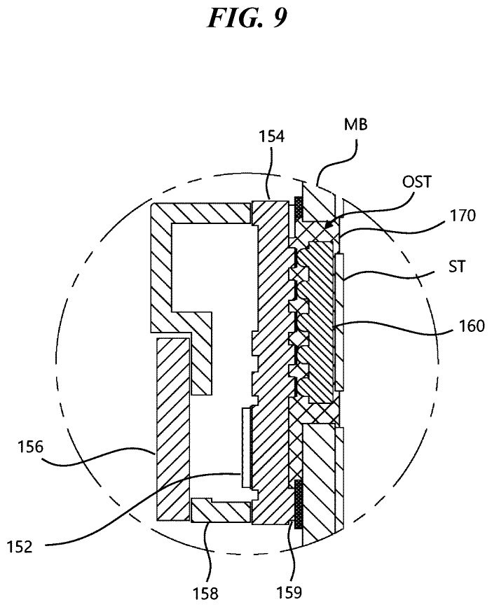

FIG. 8 is a view for explaining a light source module according to the first embodiment, and FIG. 9 is an enlarged view of a two-dot chain line portion of FIG. 8. FIG. 8 is a cross-sectional view taken along line B-B′ of FIG. 1.

Referring to FIG. 8 and FIG. 9, the light source module TXM may be coupled to the main board MB so that the driving IC 160 is positioned in the open region of the main board MB. The light source board connection pad 159 may be formed on the lower side of the optical board 154 of the light source module TXM, and the optical board 154 may be coupled to the main board MB through this light source board connection pad 159.

The stiffener ST is coupled to the lower side of the main board MB, and may have an open portion OST at a location corresponding to some of the open regions of the main board MB. When the driving IC 160 is directly in contact with the stiffener ST, the heat generated in the driving IC 160 can be directly transferred to the stiffener ST, but when the driving IC 160 and the stiffener ST are not in contact with each other, the heat of the driving IC 160 may not be directly transferred to the stiffener ST.

In order to smoothly discharge the heat of the driving IC 160, a thermal interface material (TIM) 170 can be injected into a space between the driving IC 160 and the stiffener ST. This TIM 170 may be injected through the open portion OST of the stiffener ST.

The TIM 170 may also transfer heat transferred to light source board 154 to stiffener ST. A lot of heat may be generated from light source 152 disposed on light source board 154, and a significant portion of this heat may be transferred to light source board 154. The TIM 170 can play a role in smoothly transferring this heat to stiffener ST.

As can be seen in the cross-section in the B-B′ direction, the light source 152 stacked on the upper surface of light source board 154 and the driving IC 160 under-stacked on the lower surface thereof may not overlap each other in a direction perpendicular to light source board 154. Depending on this arrangement position, heat generated from light source 152 may be prevented from being directly transferred to driving IC 160.

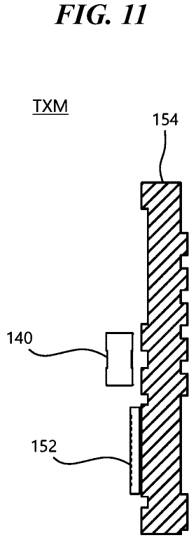

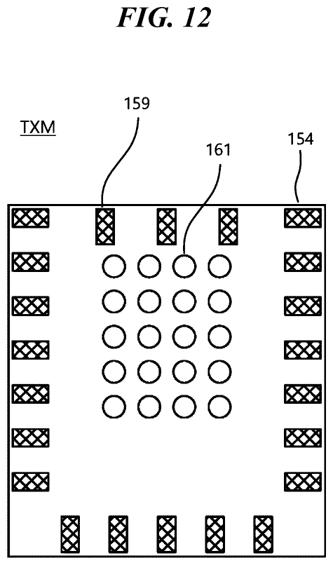

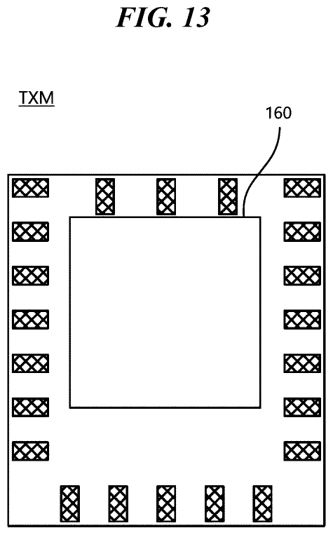

FIG. 10 is a top view of the light source module according to the first embodiment. In addition, FIG. 11 is a cross-sectional view taken along line C-C′ of FIG. 10, FIG. 12 is a view before the driving IC is attached to a lower surface of the light source module according to the first embodiment, and FIG. 13 is a view after the driving IC is attached to the lower surface of the light source module according to the first embodiment.

Referring to FIGS. 10 to 13, a plurality of components 140 and 152 may be disposed inside a position in the light source board 154 to which the light source module frame is coupled. The plurality of components 140 and 152 may include passive elements 140 such as a capacitor and resistor, and a light source 152.

Two or more light sources 152 may be disposed on the light source board 154. One of the two or more light sources 152 may be used for long-distance use, and the other may be used for short-distance use.

A plurality of pads 159 and 161 may be formed on the bottom surface of the light source board 154. Among the plurality of pads 159 and 161, the light source board connection pads 159 may be connected to the main board, and the driving IC connection pads 161 may be connected to the driving IC 160.

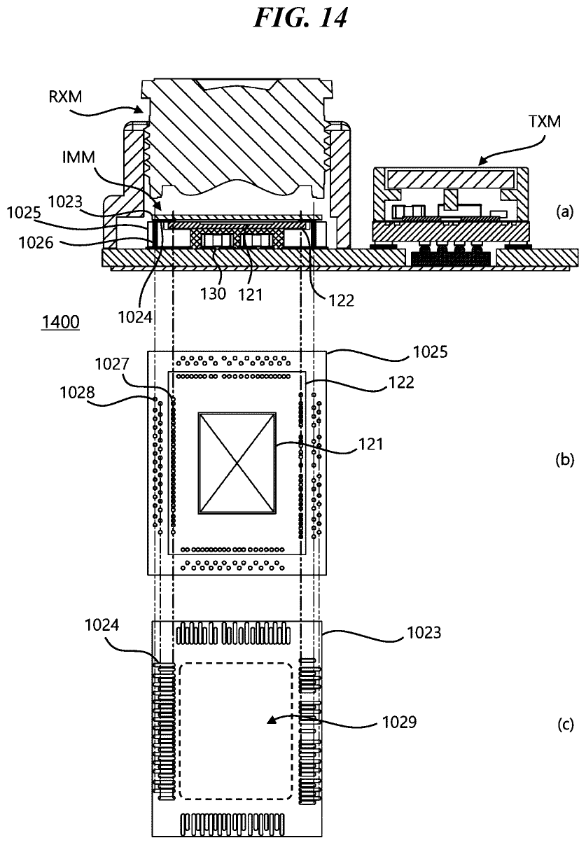

FIG. 14 is a cross-sectional view of an optical package according to a second embodiment and a top view of a sensor module.

When comparing the first embodiment and the second embodiment, in the first embodiment, the optical sensor board is connected to the main board using the wire, but in the second embodiment, the optical sensor board is connected by a conductor 1026 penetrating a spacer 1025 without a wire, which is different from the first embodiment.

Referring to FIG. 14, the spacer 1025 may have a cross-section in the shape of an “L”. Moreover, the optical sensor board 122 may be supported by the lower portion of the ‘L’ shape, and an optical filter 1023 may be supported by the higher portion thereof.

The conductor 1026 electrically connecting the upper and lower sides of the spacer 1025 may be disposed inside the spacer 1025 so as to penetrate the spacer 1025 upward and downward. Moreover, a conductor pad 1028 may be formed in a portion of the spacer 1025 that contacts the upper side of the conductor 1026.

A plurality of sensor pads 1027 may be formed on the outer surface of the optical sensor board 122. Moreover, a plurality of long connection pads 1024 may be formed on the outer surface of the lower side of the optical filter 1023.

One end of the connection pad 1024 may be in contact with the conductor pad 1028, and the other end may be in contact with the sensor pads 1027.

According to this arrangement, when the optical filter 1023 is mounted on the spacer 1025, an electrical path connected to the main board, the conductor 1026, the connection pad 1024, and the sensor pad 1027 may be formed.

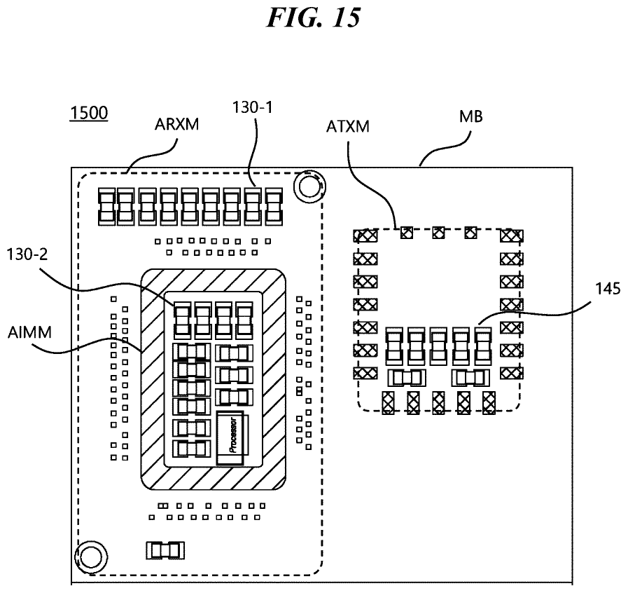

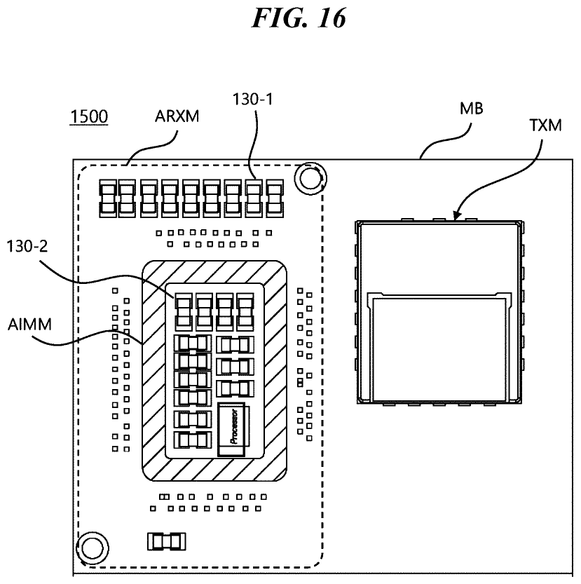

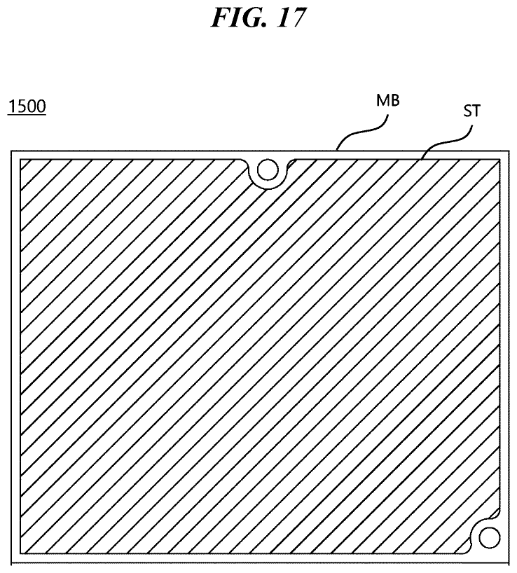

FIG. 15 is a view illustrating some components attached to a main board in an optical package according to a third embodiment, and FIG. 16 is a view illustrating a light source module completed in FIG. 15. Moreover, FIG. 17 is a bottom view of the optical package according to the third embodiment.

When comparing the first embodiment and the third embodiment, in the first embodiment, there is the open region in the light source module region of the main board MB, while in the third embodiment, components 145 may be arranged in the light source module region ATXM of the main board MB.

Referring to FIGS. 15 to 17, in an optical package 1500, the light source module region ATXM and the receiving module region ARXM are formed in the main board MB, and the components 145 for driving the light source may be disposed on the upper side of the main board MB in the light source module region ATXM. In addition, the components 130-2 may also be arranged in the sensor module region AIMM, and these components 130-2 may be components that process the signals of the optical sensor. The components 130-1 may be arranged outside the sensor module region AIMM and inside the receiver module (ARXM).

Unlike the first embodiment, in the third embodiment, the open region may not be formed in the portion where the driving IC is located.

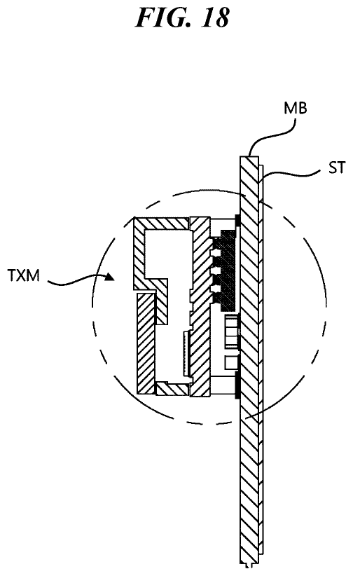

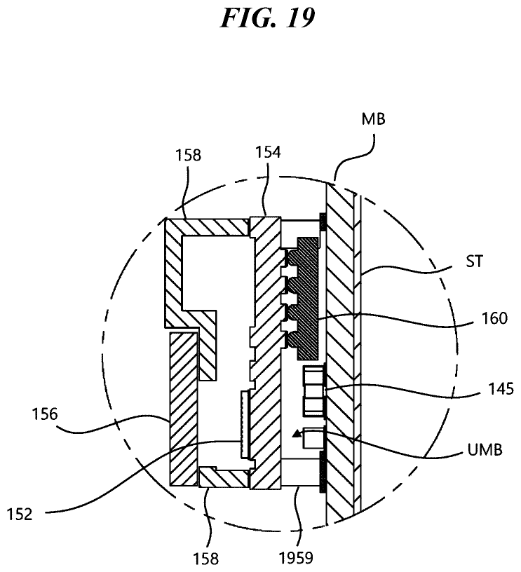

FIG. 18 is a view for explaining the light source module according to the third embodiment, and FIG. 19 is an enlarged view of a two-dot chain line portion of FIG. 18.

Referring to FIG. 18 and FIG. 19, a conductor spacer 1959 may be arranged on the outer portion of the light source module region on the main board MB. Moreover, the light source module may be disposed on the conductor spacer 1959.

In the light source module, the optical board 154 may be spaced apart from the main board MB by a certain distance or more by the conductor spacer 1959. In this way, a separation space UMB may be formed on the lower side of the light source board 154 while the optical board 154 and the main board MB are separated from each other. Then, the driving IC 160 may be disposed in this separation space UMB, and components 145 may be disposed.

In the separation space UMB, the components 145 such as passive elements (for example, capacitors and resistors) may be attached to the main board MB and electrically connected. Then, the driving IC 160 may be attached to the light source board 154 and electrically connected.

The conductor spacer 1959 may be constituted by a conductor or may include a conductor. The main board MB and the light source board 154 may be electrically connected to each other by this conductor spacer 1959.

A spacer may be used to separate the optical sensor board from the main board in the sensor module, and this spacer may be a non-conductor spacer. A large number of signal connections may be required between the optical sensor board and the main board. Accordingly, there may be limitations in electrical connection using the spacer itself. In contrast, the number of electrical connection lines between the light source board 154 and the main board MB may be relatively small. Accordingly, the light source board 154 and the main board MB may be electrically connected using the conductor spacer 1959.

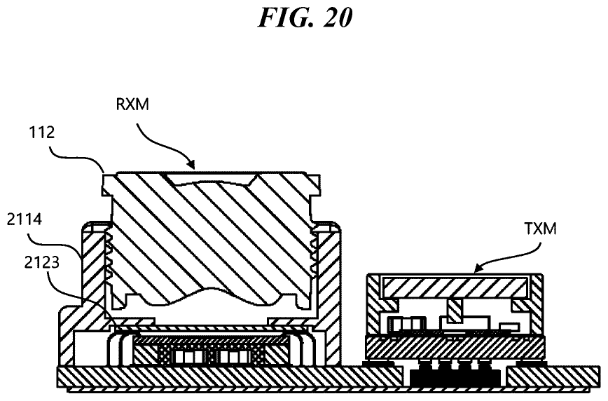

FIG. 20 is a cross-sectional view of an optical package according to a fourth embodiment.

Referring to FIG. 20, in the fourth embodiment, an optical filter 2123 may be coupled to an optical holder 2114. According to this structure, only a spacer is required to support the optical sensor board upward, and the spacer does not need to support the optical filter 2123. In addition, the optical sensor board and the main board may be connected to each other using a wire.

As described above, according to this embodiment, the volume of the optical package including the light source module and the sensor module can be reduced, and the arrangement of components can be optimized to reduce signal loss and minimize the influence of noise. In addition, according to this embodiment, the heat generated from the light source can be efficiently discharged.

The terms “include”, “constitute”, or “have” described above, unless otherwise specifically stated, mean that the corresponding component can be included, and therefore should be interpreted as including other components rather than excluding other components. All terms, including technical or scientific terms, unless otherwise defined, have the same meaning as commonly understood by a person having ordinary skill in the art to which the present disclosure pertains. Commonly used terms, such as terms defined in the dictionary, should be interpreted as being consistent with the meaning in the context of the relevant technology, and shall not be interpreted in an ideal or overly formal sense unless explicitly defined in the present disclosure.

The above description is merely an exemplary description of the technical idea of the present disclosure, and those having ordinary skill in the art to which the present disclosure pertains may make various modifications and variations without departing from the essential characteristics of the present disclosure. Therefore, the embodiments disclosed in the present disclosure are not intended to limit the technical idea of the present disclosure but to explain it, and the scope of the technical idea of the present disclosure is not limited by these embodiments. The scope of protection of the present disclosure should be interpreted by the claims below, and all technical ideas within a scope equivalent thereto should be interpreted as being included in the scope of the rights of the present disclosure.

What is claimed is:

1. An optical package comprising:
a light source module including a light source, a first component for driving the light source, and a light source board having a first side on which the light source is stacked and a second side on which the first component is under-stacked;
a main board in which a first region is open and to which the light source module is coupled so that the first component is positioned in the first region; and
a sensor module including an optical sensor board disposed to be spaced apart from the main board through a spacer, and a second component disposed in a separation space between the optical sensor board and the main board.

2. The optical package of claim 1, wherein the spacer includes a first-stage spacer disposed on a lower side and a second-stage spacer disposed on an upper side of the first-stage spacer, and
the optical sensor board is supported by the first-stage spacer, and an optical filter is supported by the second-stage spacer.

3. The optical package of claim 1, wherein the light source module further includes a light source module frame that surrounds the light source and supports an optical component upward, and
a third component is disposed in a separation space between the light source board and the optical component inside the light source module frame.

4. The optical package of claim 1, wherein the light source module is coupled to a first side of the main board, and a stiffener is attached to a second side of the main board.

5. The optical package of claim 4, wherein a portion of a part of the stiffener corresponding to the first region is open.

6. The optical package of claim 5, wherein a thermal interface material (TIM) is injected into the open portion of the stiffener.

7. The optical package of claim 1, wherein a portion where the light source is stacked on a first side surface of the light source board and a portion where the first component is under-stacked on a second side surface do not overlap each other in a direction perpendicular to the light source board.

8. The optical package of claim 1, wherein the spacer has an “L” shape in cross section, and the optical sensor board is supported by a lower portion of the “L” shape, and the optical filter is supported by a higher portion of the “L” shape.

9. The optical package of claim 8, wherein a conductor electrically connecting an upper side and a lower side of the spacer is disposed inside the spacer so as to penetrate the spacer, a connection pad is formed on a lower side of the optical filter, one end of the connection pad is in contact with a sensor pad formed on an upper side of the optical sensor board, and the other end of the connection pad is in contact with the conductor.

10. The optical package of claim 1, further comprising an optical holder that surrounds the sensor module and positions an optical receiving lens above the sensor module,
wherein the optical holder supports the optical filter so that the optical filter is positioned between the optical receiving lens and the optical sensor board.

11. An optical package comprising:
a light source module including a light source, a first component for driving the light source, and a light source board having a first side on which the light source is stacked and a second side on which the first component is under-stacked;
a main board which supplies electricity to the light source board while separating the light source board upwardly through a conductor spacer, and in which a fourth component is disposed in a separation space formed between the main board and the light source board by the conductor spacer; and
a sensor module including an optical sensor board disposed to be spaced apart from the main board through a non-conductor spacer, and a second component disposed in a separation space between the optical sensor board and the main board.

12. The optical package of claim 11, wherein the light source module further includes a light source module frame that surrounds the light source and supports an optical component upward, and
a third component is disposed in a separation space between the light source board and the optical component inside the light source module frame.

13. The optical package of claim 11, wherein the light source module is coupled to a first side of the main board, and a stiffener is attached to a second side of the main board.

14. The optical package of claim 11, wherein a portion where the light source is stacked on a first side surface of the light source board and a portion where the first component is under-stacked on a second side surface do not overlap each other in a direction perpendicular to the light source board.

15. The optical package of claim 11, wherein the non-conductor spacer includes a first-stage spacer disposed on a lower side and a second-stage spacer disposed on an upper side of the first-stage spacer, and
the optical sensor board is supported by the first-stage spacer, and an optical filter is supported by the second-stage spacer.
